(19) United States
(12) Patent Application Publication
(10) Pub. No.: US 2023/0185188 A1
(43) Pub. Date: Jun. 15, 2023

(54) DRAWING METHOD, MASTER PLATE MANUFACTURING METHOD, AND DRAWING APPARATUS

(71) Applicant: KIOXIA CORPORATION, Tokyo (JP)

(72) Inventor: Yoshinori KAGAWA, Shinagawa Tokyo (JP)

(21) Appl. No.: 17/884,117

(22) Filed: Aug. 9, 2022

(30) Foreign Application Priority Data
Dec. 15, 2021 (JP) 2021-203710

(51) Int. Cl. G03F 1/78; G03F 7/20; G03F 9/00

(52) U.S. Cl. CPC G03F 1/78; G03F 7/2063; G03F 9/7049

(57) ABSTRACT

According to one embodiment, a pattern drawing method includes correcting a drawing parameter for a pattern to be drawn on a resist film on a surface of a substrate. The correction being based on drawing information, height information, and dimensional difference information. The drawing information is design data for drawing the pattern on the resist film by irradiating the resist film with an electron beam. The height information indicates changes in surface height of the substrate. The dimensional difference information includes differences between a dimension of a pattern as indicated in the design data and a dimension of a pattern formed on the substrate by processing the substrate using a resist film patterned according to the drawing information as a mask. The correction of the drawing parameter reduces a dimensional difference between design data and a pattern formed on a target portion on the surface of the substrate.

### CROSS-REFERENCE TO RELATED APPLICATION

This application is based upon and claims the benefit of priority from Japanese Patent Application No. 2021-203710, filed Dec. 15, 2021, the entire contents of which are incorporated herein by reference.

### FIELD

Embodiments described herein relate generally to a drawing method, a master plate manufacturing method, and a drawing apparatus.

### BACKGROUND

A master plate, such as a photomask or an imprint lithography template, for a semiconductor device manufacturing process may be produced by forming a pattern on a substrate using an electron beam drawing apparatus. However, it may be difficult to form a pattern with high-dimensional accuracy on a substrate for which the height of the substrate surface being patterned varies.

### BRIEF DESCRIPTION OF THE DRAWINGS

FIG. 1A illustrates an example of a drawing apparatus according to a first embodiment.

FIG. 1B illustrates another example of a drawing apparatus according to a first embodiment.

FIG. 2A is a cross-sectional view showing an example of a mask blank to which the drawing apparatus according to a first embodiment can be applied.

FIG. 2B is a cross-sectional view showing an example of a template blank to which the drawing apparatus according to a first embodiment can be applied.

FIG. 2C is a cross-sectional view showing another example of a mask blank to which the drawing apparatus according to a first embodiment can be applied.

FIG. 3 is a flowchart of a drawing method according to a first embodiment.

FIG. 4 illustrates aspects related to an acquisition of drawing data.

FIG. 5 illustrates aspects related to an acquisition of height related data shown.

FIG. 6 illustrates aspects related to an acquisition of dimensional difference data.

FIG. 7 illustrates aspects related to a method of calculating dimensional difference data.

FIG. 8 illustrates aspects related to a correction of drawing data.

FIGS. 9A to 9E are views showing aspects of a photomask manufacturing method according to a first embodiment.

FIGS. 10A to 10E are views showing aspects of a template manufacturing method according to a first embodiment.

FIG. 11 is a flowchart of a drawing method according to a second embodiment.

FIG. 12 illustrates aspects related to a correction of an irradiation amount.

FIG. 13 illustrates aspects of a method for correcting an irradiation amount.

FIG. 14 is a flowchart of a drawing method according to a third embodiment.

FIG. 15 illustrates aspects related to a calculation of an energy distribution for back scattering.

FIG. 16 illustrates additional aspects related to a calculation of an energy distribution of back scattering.

FIG. 17 illustrates further aspects related to a calculation of an energy distribution of back scattering.

FIG. 18 illustrates aspects related to a calculation of an integrated energy distribution shown.

FIG. 19 illustrates aspects related to a calculation of a required energy amount.

FIG. 20 is a flowchart of a drawing method according to a fourth embodiment.

### DETAILED DESCRIPTION

Embodiments describe a drawing method, a master plate manufacturing method, and a drawing apparatus capable of forming a pattern on a substrate that has surface height variations with high dimensional accuracy.

In general, according to one embodiment, a pattern drawing method includes correcting a drawing parameter for a pattern drawn on a resist film on a surface of a substrate. The correction being based on drawing information, height information, and dimensional difference information. The drawing information is design data for drawing the pattern on the resist film by irradiating the resist film with an electron beam. The height information indicates changes in surface height of the substrate. The dimensional difference information includes differences between a dimension of a pattern as indicated in the design data and a dimension of a pattern formed on the substrate by processing the substrate using a resist film patterned according to the drawing information as a mask. The correction of the drawing parameter reduces a dimensional difference between design data and a pattern formed on a target portion on the surface of the substrate.

Hereinafter, certain example embodiments of the present disclosure will be described with reference to the drawings. In the drawings, the same or substantially similar elements, aspects, or components are designated by the same reference numerals, and redundant descriptions may be omitted.

### First Embodiment

### Drawing Apparatus

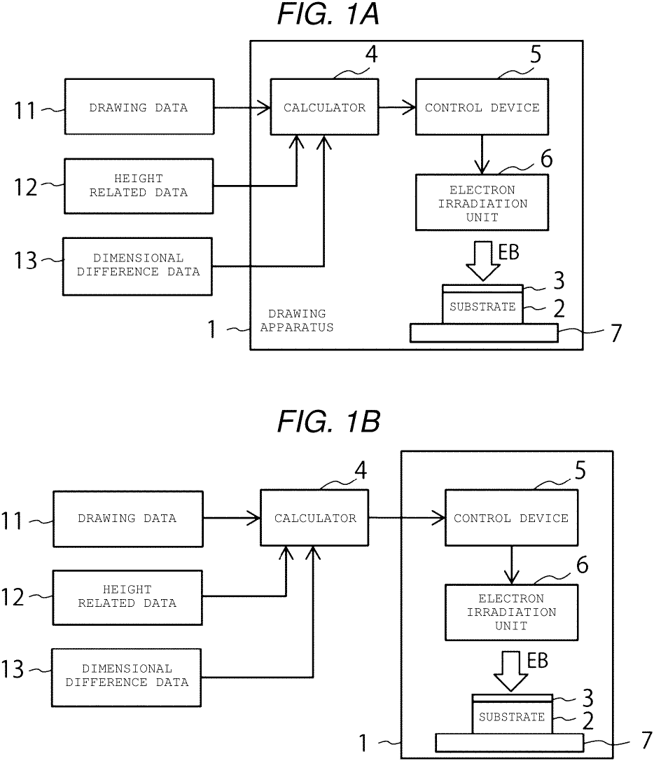

FIG. 1A is a view showing an example of a drawing apparatus 1 according to a first embodiment. FIG. 1B is a view showing another example of a drawing apparatus 1 according to the first embodiment. The drawing apparatus 1 shown in FIGS. 1A and 1B can be used, for example, to draw a pattern on a resist film 3 that is on a surface of a substrate 2. Such a pattern is drawn by irradiating the resist film 3 with an electron beam EB. The substrate 2 thus patterned (and subsequently processed) may be used as a master plate used in a semiconductor device manufacturing process or the like. However, the substrate 2 is not particularly limited in any specific aspect and, in general, any substrate type that may be patterned in an electron beam lithography process or the like corresponding to the manufacturing of a master plate by irradiating of a resist film 3 with electron beam EB may be adopted. For example, the substrate 2 may be a mask blank 2A, a mask blank 2C, or a template blank 2B. More specifically, the drawing apparatus 1 shown in FIGS. 1A and 1B can be used to correct drawing conditions (parameters) for the pattern drawn on the resist film 3 on the surface of the substrate 2 in order to form the pattern on the substrate 2 with high fidelity to an intended (design) pattern even when the height of the substrate surface changes place to place on the substrate 2. That is, the surface of substrate 2 being patterned may have already thereon features or regions of different heights.

The drawing apparatus 1 shown in FIG. 1A includes a calculator 4, a control device 5, an electron irradiation unit 6, and a stage 7. The calculator 4 performs various calculation processes (for example, correction of the dimension of the pattern drawn on the resist film 3 described later) for correcting the drawing conditions of the pattern drawn on the resist film 3. In FIG. 1A, the calculator 4 may also perform calculation processes related to the drawing other than the calculations associated with the correction of the drawing conditions in view of surface height changes.

In the drawing apparatus 1 shown in FIG. 1B, the calculator 4 is disposed outside the drawing apparatus 1. In FIG. 1B, the calculator 4 outside the drawing apparatus 1 still performs various calculation processes for correcting the drawing conditions, but the calculated corrections are externally supplied to the drawing apparatus 1 rather than internally calculated. In other examples, the drawing apparatus 1 may separately include a calculator that performs various calculation processes for drawing other than the corrections of the drawing conditions in view of surface height changes.

The following description of the drawing apparatus 1 is a description common to the drawing apparatus 1 of FIGS. 1A and 1B unless otherwise specified. The electron irradiation unit 6 is disposed in an electron optical lens barrel (column). The substrate 2 is placed on the stage 7 in a vacuum chamber communicating with the electron optical lens barrel. The stage 7 is capable of being moved in the horizontal direction (X direction, Y direction) and the vertical direction (Z direction), for example, by a driving device such as a motor. Since the stage 7 can be moved, the irradiation location of the electron beam EB with respect to the substrate 2 on the stage 7 can be changed.

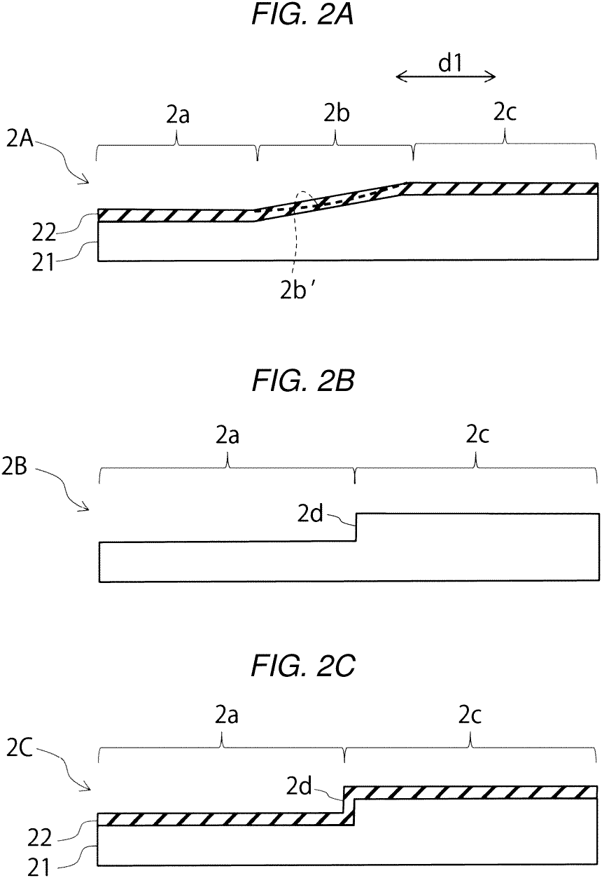

An example of the substrate 2 to which the drawing apparatus 1 can be applied will be described before the components of the drawing apparatus 1 are described in more detail. FIG. 2A is a cross-sectional view showing an example of a mask blank 2A to which the drawing apparatus 1 according to the first embodiment can be applied. FIG. 2B is a cross-sectional view showing an example of a template blank 2B to which the drawing apparatus 1 according to the first embodiment can be applied. FIG. 2C is a cross-sectional view showing an example of a mask blank 2C to which the drawing apparatus 1 according to the first embodiment can be applied. The mask blanks 2A and 2C are examples of the substrate 2 used for manufacturing a photomask which is a master plate for photolithography. The template blank 2B is an example of the substrate 2 used for manufacturing a template which is a master plate for nanoimprint lithography.

As shown in FIGS. 2A and 2C, the mask blanks 2A and 2C as the substrate 2 have a light-transmissive substrate 21 and a light shielding film 22 formed on the light-transmissive substrate 21. The light-transmissive substrate 21 may comprise quartz as a main component, for example. The light shielding film 22 may comprise, for example, a metal such as chromium (Cr) as a main component. The light shielding film 22 may be a composite layer of a MoSi layer on the lower layer side and a Cr layer on the upper layer side. On the other hand, as shown in FIG. 2B, the template blank 2B as the substrate 2 wholly light-transmissive (no light shielding film 22) and comprises quartz, for example, as a main component.

When a step or slope is present on the surface of a processing target film formed on a device substrate (wafer) to be patterned using the master plate and the master plate (a photomask or a template) has a uniformly flat surface, it becomes difficult to process the processing target film with high accuracy. Specifically, in the case of photolithography using a photomask, it becomes difficult to properly focus the light-exposure on the resist film formed on the processing target film, and then it becomes difficult to properly expose the resist film for patterning. In the case of nanoimprint lithography using a template, it becomes difficult to properly press the template against the resist on the device substrate to transfer the template pattern to the device substrate. As a result, it becomes difficult to form a circuit pattern on the processing target film with the desired accuracy. Therefore, from the viewpoint of accurately processing the processing target film that has a step or a slope, the surfaces (that is, the upper surfaces) of the substrates 2A to 2C (which can be used for a photomask or a template) have a surface shape that matches (or otherwise compensates for) the surface shape of the processing target film.

Specifically, the surface of the mask blank 2A shown in FIG. 2A has a flat portion 2a which is parallel to the in-plane direction d1, a flat portion 2c which is formed higher than the flat portion 2a, and a slope portion 2b which connects both flat portions 2a and 2c. When the mask blank 2A is placed on the stage 7, the in-plane direction d1 coincides with the horizontal direction. The slope portion 2b shown in FIG. 2A has a linear inclined plane, but as shown with dashed line slope portion 2b′ in FIG. 2A, the transition between flat portions 2a and 2c (slope portion 2b′) may be an inclined curved surface or other shape.

The surfaces of the template blank 2B shown in FIG. 2B and the mask blank 2C shown in FIG. 2C have flat portions 2a and 2c at different heights from each other and directly adjacent to each other along the in-plane direction d1. A step portion 2d connects the flat portions 2a and 2c. The template blank 2B in other examples may have a sloped portion as a transition between flat portions 2a and 2c.

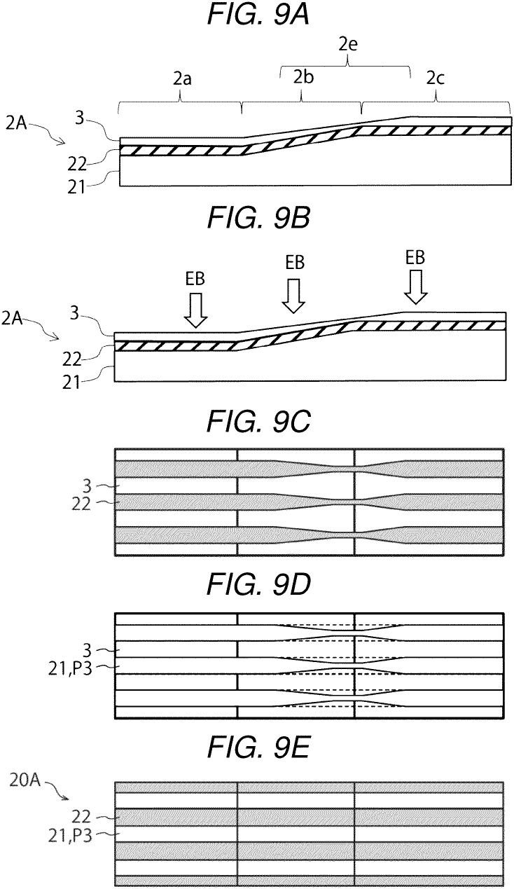

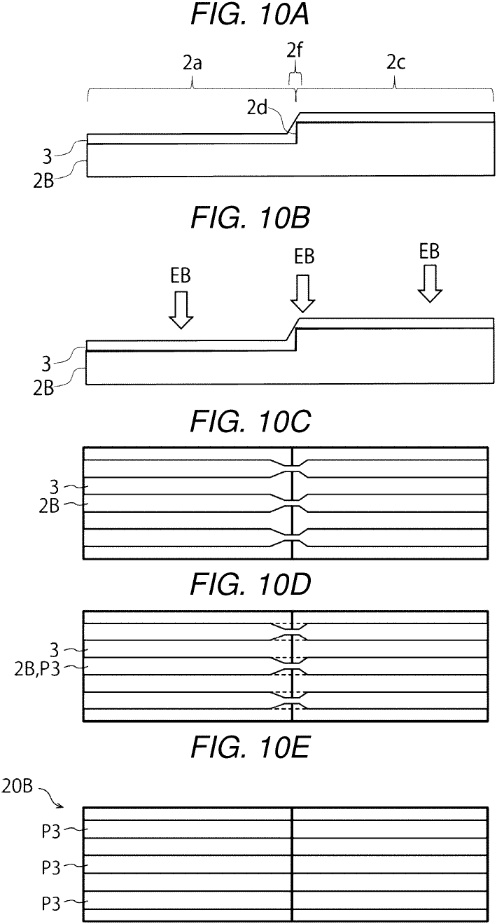

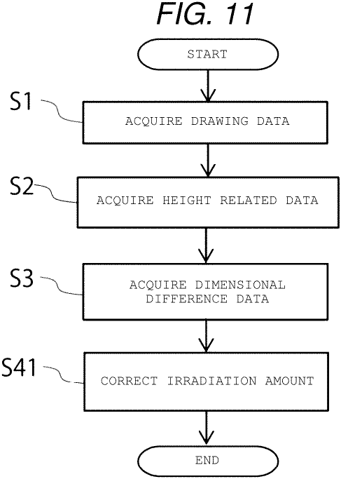

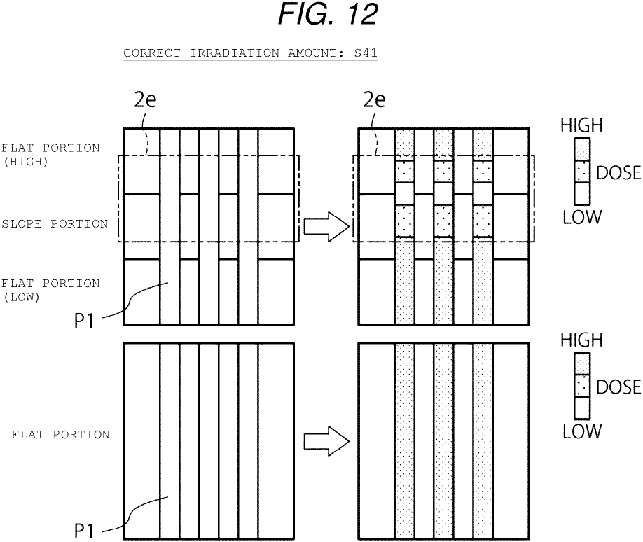

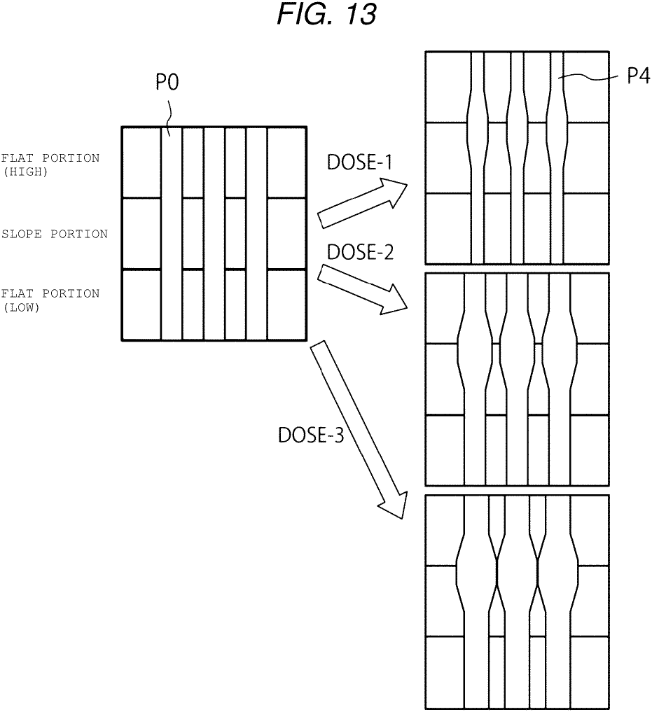

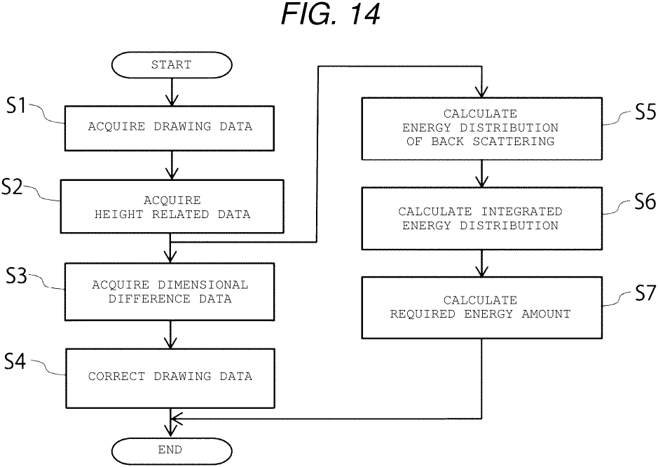

When the pattern is drawn on the substrate 2 for manufacturing the master plate (photomask, template), the resist film 3 is formed on the surface of the substrate 2. For the formation of the resist film 3, for example, rotary coating of the resist with a spin coater is used. In FIG. 9A, the resist film 3 is shown formed on the surface of the mask blank 2A. In FIG. 10A, the resist film 3 is formed on the surface of the template blank 2B. The pattern is drawn in the resist film 3 with the electron beam EB. When the height of the surface of the substrate 2 (the height along the irradiation direction of the electron beam EB) hardly changes (for example, when the height of the surface of the substrate 2 is constant), the thickness of the resist film 3 in a direction orthogonal to the surface of the substrate 2 is uniform (that is, constant).

On the other hand, when the surface of the substrate 2 includes a portion where the height changes, the thickness of the resist film 3 may change such as becoming thinner in a region near the boundary between the height changes.

In the example of the mask blank 2A shown in FIG. 9A, the thickness of the resist film 3 becomes thin at a slope boundary peripheral portion 2e on the surface of the mask blank 2A. In the example shown in FIG. 9A, the slope boundary peripheral portion 2e includes a portion of the slope portion 2b on the flat portion 2c side and a portion of the flat portion 2c on the slope portion 2b side.

In the example shown in FIG. 10A, the thickness of the resist film 3 becomes thin at a step boundary peripheral portion 2f on the surface of the template blank 2B. In the example shown in FIG. 10A, the step boundary peripheral portion 2f includes a portion of the flat portion 2c on the step portion 2d side and a portion of the flat portion 2a on the step portion 2d side.

The thickness of the resist film 3 may also be increased at the lower end side of the slope portion 2b or the step portion 2d to the flat portion 2a. Further, the thickness of the resist film 3 on the flat portion 2a near the lower end of the slope portion 2b or the step portion 2d may be thicker.

After drawing the pattern on the resist film 3, the latent pattern drawn in the resist film 3 is developed, and the substrate 2 is processed by dry etching using the developed resist film 3 as a mask, and then the pattern is formed in the substrate 2. When the height of the surface of the substrate 2 hardly changes in the plane, since the thickness of the resist film 3 is uniform, the developed resist film 3 will generally have a sufficient thickness at any place in the plane. Having a sufficient thickness, the developed resist film 3 functions appropriately as a mask, and high dimensional accuracy of the pattern formed on the substrate 2 can be ensured.

On the other hand, in a case in which the surface of the substrate 2 includes a portion where the height changes and the thickness of the resist film 3 becomes thin at a boundary peripheral portion, the thickness of the developed resist film 3 may be insufficient at the boundary peripheral portion. Due to the insufficient thickness at the boundary peripheral portion, the resist film 3 cannot properly function as a mask at the boundary peripheral portion and makes it difficult to ensure the high dimensional accuracy of the pattern formed on the substrate 2. Specifically, the substrate 2 is excessively processed at the boundary peripheral portion, and for example, the width dimension of the line pattern becomes larger than a design value.

On the other hand, the drawing apparatus 1 according to the first embodiment is configured to form a pattern on the substrate 2, on which the height of the surface changes, with high dimensional accuracy.

Specifically, as shown in FIGS. 1A and 1B, drawing data 11 is input to the calculator 4 from the outside. The drawing data 11 is data used for drawing the pattern on the resist film 3 with the electron beam EB. The drawing data 11 is, for example, data created by a calculator different from the calculator 4 based on the design data for the master plate. Further, as shown in FIGS. 1A and 1B, height related data 12 is input to the calculator 4 from the outside. The height related data 12 is information related to the heights of the surface of the substrate 2. The irradiation direction of the electron beam EB is a direction orthogonal to the in-plane direction d1 of the substrate 2 and is a direction indicated by an arrow EB (that is, the downward arrow) in the examples shown in FIGS. 1A and 1B. The height related data 12 is, for example, data created by a calculator different from the calculator 4 based on the design data for the master plate. Further, as shown in FIGS. 1A and 1B, dimensional difference data 13 is input to the calculator 4 from the outside. The dimensional difference data 13 is information related to a difference (hereinafter, also referred to as a pattern dimensional difference) between the dimension of a pattern indicated in the drawing data 11 and the dimension of a pattern actually formed on the substrate 2 by processing the substrate 2 using the resist film 3 as a mask. The dimensional difference data 13 is data created by a calculator different from the calculator 4 based on, for example, the drawing data and pattern formation results (for example, an experimental result or a simulation result) on the substrate 2 using the drawing data. A method for inputting the drawing data 11, the height related data 12, and the dimensional difference data 13 to the calculator 4 is not particularly limited and may be, for example, either an input by data communication (e.g., network transfer) or an input via a storage medium.

The calculator 4 corrects the drawing conditions for the pattern that is drawn on the resist film 3 on the surface of the substrate 2 based on the drawing data 11, the height related data 12, and the dimensional difference data 13 input from the outside. The correction of the drawing conditions is performed such that the pattern dimensional difference is reduced in the pattern corresponding to the boundary peripheral portion. The correction of the drawing conditions may also be performed such that the pattern dimensional difference is reduced in areas outside the boundary peripheral portion.

In the first embodiment, the correction of the drawing conditions includes the changing of the dimension of the pattern drawn on the resist film 3 in the boundary peripheral portion. The correction of the drawing conditions may also include the changing of the dimension of the pattern drawn on the resist film 3 outside the boundary peripheral portion.

The changing (correction) of the dimension of the pattern drawn on the resist film 3 on the boundary peripheral portion includes reducing or increasing the dimension of the pattern drawn on the resist film 3 on the boundary peripheral portion to reduce the pattern dimensional difference. The changing (correction) of the dimension of the pattern drawn on the resist film 3 on a target portion different from the boundary peripheral portion includes reducing or increasing the dimension of the pattern drawn on the resist film 3 on the target portion to reduce the pattern dimensional difference.

The correction of the dimension of the pattern drawn on the resist film 3 includes the adjusting of the drawing data 11 indicating the pattern drawn on the resist film 3.

The calculator 4 outputs the corrected drawing data 11 to the control device 5.

The control device 5 controls irradiation on the resist film 3 with the electron beam EB by the electron irradiation unit 6 (that is, drawing of the pattern) based on the drawing data input from the calculator 4. For example, the control device 5 controls the irradiation with the electron beam EB so that a pattern of corrected dimension is drawn on the resist film 3 on the boundary peripheral portion. The electron irradiation unit 6 includes, for example, an electron gun that emits the electron beam EB and an electron optical system (deflector, electromagnetic lens, or the like) that controls the trajectory of the emitted electron beam EB.

When the drawing condition of the pattern with respect to the resist film 3 on a boundary peripheral portion having an insufficient thickness is the same as used for other than the boundary peripheral portion, the resist film 3 on the boundary peripheral portion does not properly function as a mask after the development, and the substrate 2 is excessively processed at the boundary peripheral portion. When the substrate 2 is excessively processed, the dimension of the pattern becomes excessive in the boundary peripheral portion. In contrast to this, according to the drawing apparatus 1 of the first embodiment, the drawing condition can be corrected such that the pattern dimensional difference is reduced in the pattern corresponding to the boundary peripheral portion. As a result, the pattern can be formed on the substrate 2, in which the height of the surface changes, with high dimensional accuracy.

### Drawing Method

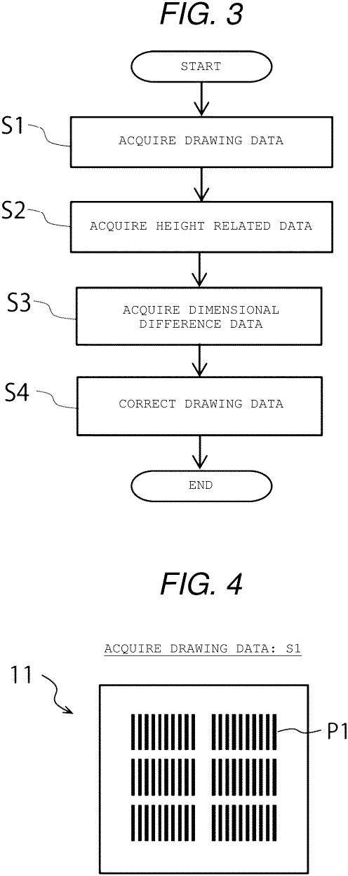

Hereinafter, an embodiment of a drawing method to which the drawing apparatus 1 according to the first embodiment can be applied will be described. FIG. 3 is a flowchart showing an example of a drawing method according to the first embodiment.

As shown in FIG. 3, first, the calculator 4 acquires the drawing data 11 from the outside (step S1). FIG. 4 is a view showing an example of an acquisition step of the drawing data 11 shown in the flowchart of FIG. 3. As shown in FIG. 4, the drawing data 11 indicates a two-dimensional region corresponding to the surface of the substrate 2 and has a pattern P1 defined in the region. The pattern P1 on the drawing data 11 is drawn at a corresponding location (that is, coordinates) on the surface of the substrate 2. Since the drawing data 11 is two-dimensional data, it does not have information regarding the height changes on the substrate 2 such as a slope portion or a step portion on the surface of the substrate 2. The specifics of the drawing data 11 is not limited to the aspects shown in FIG. 4.

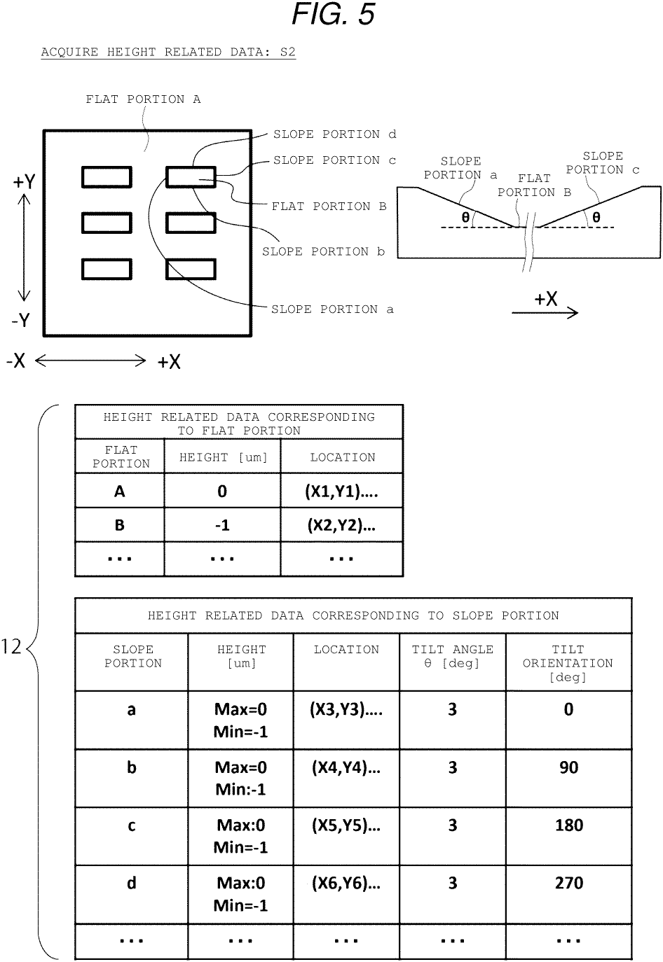

Further, as shown in FIG. 3, the calculator 4 acquires the height related data 12 from the outside (step S2). The acquisition of the height related data 12 may be exchanged before and after the acquisition of the drawing data 11 or may be performed in parallel. FIG. 5 is a view showing an example of an acquisition step of the height related data 12 shown in the flowchart of FIG. 3. As shown in FIG. 5, the height related data 12 includes height data indicating the height (µm) of the surface of the substrate 2. In the example shown in FIG. 5, the height data includes height data of the flat portion and height data of the slope portion. In the example shown in FIG. 5, the height data is data indicating a relative height based on the height of one flat portion among the plurality of flat portions (0 µm). Further, in the example shown in FIG. 5, the height related data 12 includes location data indicating disposition locations (a range of the X coordinate and the Y coordinate) of the surface having the height indicated in the height data. Further, in the example shown in FIG. 5, the height related data 12 includes tilt angle data indicating a tilt angle θ deg of the slope portion as data capable of calculating the height corresponding to each location in the slope portion. Further, in the example shown in FIG. 5, the height related data 12 includes tilt orientation data indicating an orientation (deg) of the slope portion as data capable of calculating the height corresponding to each location in the slope portion. More specifically, in the example shown in FIG. 5, the tilt orientation data is data in which the two-dimensional direction where the height of the slope portion decreases is represented by an angle formed by the +X direction shown in FIG. 5. For example, the slope portion a shown in FIG. 5 has a tilt orientation of 0 deg because the two-dimensional direction in which the height of the slope portion decreases coincides with the +X direction. On the other hand, the slope portion c shown in FIG. 5 has a tilt orientation of 180 deg because the two-dimensional direction in which the height of the slope portion c decreases is opposite to the +X direction. In the example shown in FIG. 5, the height data of the slope portion includes only the maximum value and the minimum value, and the calculator 4 can calculate the height between the maximum value and the minimum value based on the location data, the tilt angle data, and the tilt orientation data. The height data may include a plurality of heights between the maximum value and the minimum value. In that case, the location data may be correlated to each of a plurality of heights. Further, as shown in FIG. 5, the height related data 12 may be data in a table format. The specifics of the height related data 12 is not limited to the aspects shown in FIG. 5.

Further, as shown in FIG. 3, the calculator 4 acquires the dimensional difference data 13 from the outside (step S3). The acquisition of the dimensional difference data 13 may be exchanged before and after the acquisition of the drawing data 11 or may be performed at the same time.

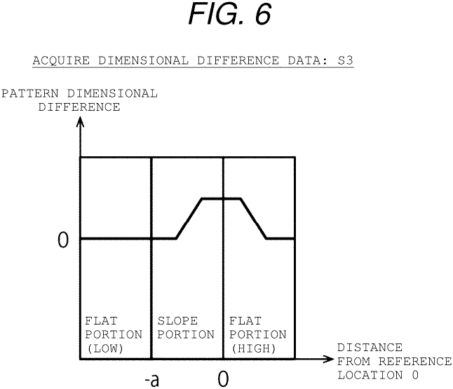

FIG. 6 is a view showing an example of an acquisition step of the dimensional difference data 13 shown in the flowchart of FIG. 3. In the example shown in FIG. 6, the dimensional difference data 13 is data in which a distance in the tilt orientation direction of the slope portion, where the boundary between the slope portion and the flat portion connected to the upper end of the slope portion is set as a reference location (0), is defined as the horizontal axis and the pattern dimensional difference is defined as the vertical axis. As described above, the pattern dimensional difference is the difference between the dimension of the pattern indicated in the drawing data 11 and the dimension of the pattern formed on the substrate 2 after processing of the substrate 2 using the developed resist film 3 as a mask.

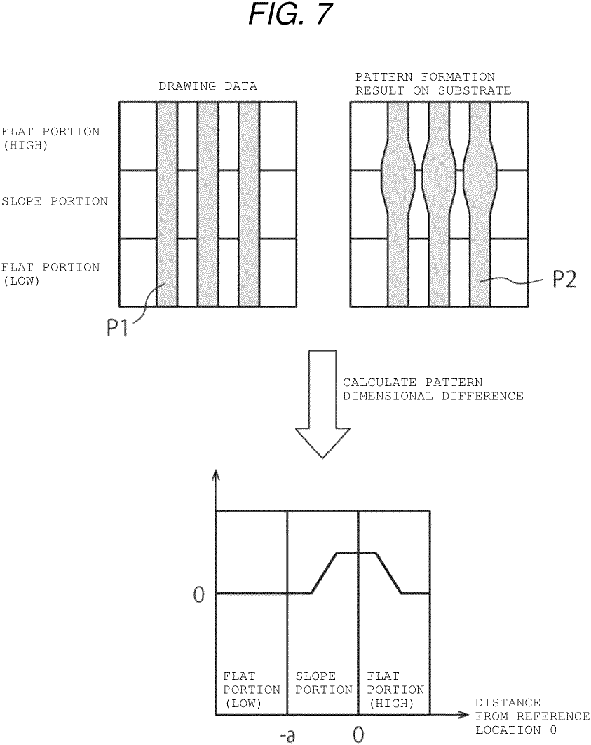

FIG. 7 is a descriptive view illustrating an example of a calculation method of the dimensional difference data shown in FIG. 6 in the drawing method according to the first embodiment. For example, as shown in FIG. 7, the dimensional difference data 13 can be acquired by comparing the pattern P1 indicated in the drawing data with the formation result (the pattern P2) on the substrate 2 acquired by experiment or simulation and calculating the dimensional difference between both patterns P1 and P2.

After acquiring the drawing data 11, the height related data 12, and the dimensional difference data 13, as shown in FIG. 3, the calculator 4 corrects the drawing data (step S4). The correction of the drawing data is performed so as to adjust the dimension of the pattern drawn on the resist film 3 on the boundary peripheral portion in order to reduce the pattern dimensional difference.

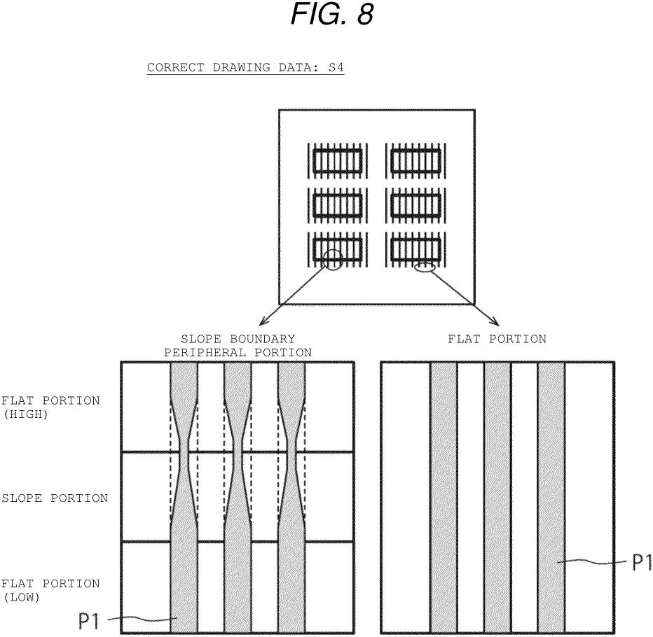

FIG. 8 is a view showing an example of a correction step of the drawing data shown in the flowchart of FIG. 3 in the drawing method according to the first embodiment. In the example shown in FIG. 8, the correction of the drawing data is performed so as to reduce the dimension of the pattern P1 drawn on the resist film 3 on the slope boundary peripheral portion 2e according to the pattern dimensional difference. More specifically, the correction of the drawing data is performed so as to reduce the dimension of the pattern P1 drawn on the resist film 3 on the slope boundary peripheral portion 2e with a reduction amount that cancels the pattern dimensional difference shown in FIG. 6.

In the example shown in FIG. 8, the drawing data is corrected such that the width dimension of the line pattern P1 drawn on the resist film 3 on the slope boundary peripheral portion 2e becomes smaller than the width dimension of the line pattern P1 drawn on the resist film 3 on other than the slope boundary peripheral portion 2e. In FIG. 8, the line pattern P1 on the slope boundary peripheral portion 2e before the correction is indicated by a broken line. The drawing data is not adjusted for the pattern P1 drawn on the resist film 3 on the normal flat portion.

When the calculator 4 is in the drawing apparatus 1 as shown in FIG. 1A, the correction of the drawing data by the calculator 4 (step S4) is performed in the drawing apparatus 1. On the other hand, when the calculator 4 is outside the drawing apparatus 1 as shown in FIG. 1B, the correction of the drawing data by the calculator 4 (step S4) is performed outside the drawing apparatus 1.

The drawing step of the pattern based on the corrected drawing data will be described in the following master plate manufacturing method.

### Master Plate Manufacturing Method

The drawing method according to the first embodiment described with reference to FIGS. 3 to 8 can be used for manufacturing a master plate. Hereinafter, as a master plate manufacturing method to which the drawing method according to the first embodiment is applied, an embodiment of a manufacturing method of a photomask and an embodiment of a manufacturing method of a template will be described in order.

FIG. 9A is a cross-sectional view showing the manufacturing method of the photomask according to the first embodiment. In the manufacture of the photomask, first, as shown in FIG. 9A, the resist film 3 is formed on the mask blank 2A described with reference to FIG. 2A. The formation of the resist film 3 includes coating the resist film 3 and baking after the coating (a post-applied bake). In the example shown in FIG. 9A, the resist film 3 is a positive type (positive tone resist). The resist film 3 may be a negative type (negative tone resist) in some examples. As shown in FIG. 9A, the thickness of the resist film 3 is assumed to be thin at the slope boundary peripheral portion 2e.

FIG. 9B is a cross-sectional view showing the manufacturing method of the photomask according to the first embodiment, following FIG. 9A. After forming the resist film 3, as shown in FIG. 9B, the electron irradiation unit 6 of the drawing apparatus 1 irradiates the resist film 3 with the electron beam EB according to the drawing data 11 corrected by using the drawing method according to the first embodiment. As a result, a portion of the resist film 3 that is irradiated with the electron beam EB is exposed, and the pattern is thus drawn on the resist film 3. In the example shown in FIG. 9B, the width dimension of the line pattern drawn on the resist film 3 on the slope boundary peripheral portion 2e is smaller than the width dimension of the line pattern drawn on the resist film 3 outside the slope boundary peripheral portion 2e.

FIG. 9C is a plan view showing the manufacturing method of the photomask according to the first embodiment, following FIG. 9B. After baking the resist film 3 again (a post-exposure bake), the resist film 3 is developed as shown in FIG. 9C. The development of the resist film 3 is performed by a wet process using a chemical solution. By the development, the exposed portion of the resist film 3 is removed, and the light shielding film 22 is exposed where the resist film 3 is removed.

FIG. 9D is a plan view showing the manufacturing method of the photomask according to the first embodiment, following FIG. 9C. After developing the resist film 3, the light shielding film 22 is etched (or otherwise processed) using the developed resist film 3 as a mask. The etching is performed in a dry process.

The thickness of the resist film 3 on the slope boundary peripheral portion 2e is thinner than the thickness of the resist film 3 elsewhere. The dimension of the light shielding film 22 exposed on the slope boundary peripheral portion 2e by the development (that is, the width dimension of the line pattern) is smaller than the dimension (line width) of the light shielding film 22 outside slope boundary peripheral portion 2e. Thereby, the dimension of the pattern formed on the mask blank 2A by the processing of the light shielding film 22 can be made more uniform between the slope boundary peripheral portion 2e and the surface of the mask blank 2A other than the slope boundary peripheral portion 2e.

FIG. 9E is a plan view showing the manufacturing method of the photomask according to the first embodiment, following FIG. 9D. After etching the light shielding film 22, the resist film 3 is removed as shown in FIG. 9E. As a result, a photomask 20A having a uniform pattern width can be obtained.

Next, the manufacturing method of the template according to the first embodiment will be described. The description that overlaps with the manufacturing method of the photomask 20A already described with reference to FIGS. 9A to 9E may be omitted.

FIG. 10A is a cross-sectional view showing the manufacturing method of a template according to the first embodiment. In the manufacture of the template, first, as shown in FIG. 10A, the resist film 3 is formed on the template blank 2B described with reference to FIG. 2B. In the example shown in FIG. 10A, the resist film 3 is a positive type. As shown in FIG. 10A, the thickness of the resist film 3 becomes thinner at the step boundary peripheral portion 2f. The thickness of the resist film 3 in the step boundary peripheral portion 2f may also be thicker than portions outside step boundary peripheral portion 2f.

FIG. 10B is a cross-sectional view showing the manufacturing method of the template according to the first embodiment, following FIG. 10A. After forming the resist film 3, as shown in FIG. 10B, the electron irradiation unit 6 of the drawing apparatus 1 irradiates the resist film 3 with the electron beam EB according to the drawing data 11 as corrected by using the drawing method according to the first embodiment. As a result, a portion of the resist film 3 that is irradiated with the electron beam EB is exposed, and the pattern is drawn on the resist film 3.

In the example shown in FIG. 10B, the width dimension of the line pattern drawn on the resist film 3 on the step boundary peripheral portion 2f becomes smaller than the width dimension of the line pattern drawn on the resist film 3 outside the step boundary peripheral portion 2f.

FIG. 10C is a plan view showing the manufacturing method of the template according to the first embodiment, following FIG. 10B. After a post-exposure baking of the resist film 3, the resist film 3 is developed as shown in FIG. 10C. By the development, the exposed portion of the resist film 3 is removed, and the surface of the template blank 2B is exposed where the resist film 3 is removed.

FIG. 10D is a plan view showing the manufacturing method of the template according to the first embodiment, following FIG. 10C. After developing the resist film 3, the template blank 2B is etched (or otherwise processed) using the developed resist film 3 as a mask.

The thickness of the resist film 3 on the step boundary peripheral portion 2f is thinner than the thickness of the resist film 3 outside the step boundary peripheral portion 2f. The line width dimension of the surface of the template blank 2B exposed on the step boundary peripheral portion 2f is smaller than the line width dimension of the surface outside the step boundary peripheral portion 2f. Thereby, the dimension of the pattern formed on the template blank 2B by the processing of the template blank 2B can be made more uniform.

FIG. 10E is a plan view showing the manufacturing method of the template according to the first embodiment, following FIG. 10D. After etching the template blank 2B, the resist film 3 is removed as shown in FIG. 10E. As a result, the template 20B having a uniform pattern width can be obtained.

According to the manufacturing methods of the photomask 20A and the template 20B according to the first embodiment, the resist film 3 can be irradiated with the electron beam EB according to the drawing data 11 which has been corrected by using the drawing method according to the first embodiment. As a result, the pattern can be formed on the photomask 20A and the template 20B with high dimensional accuracy even though the height of the surface of these master plates is not constant. By applying the photomask 20A and the template 20B having the pattern with high dimensional accuracy to the semiconductor process, more accurate dimensional patterns can be formed on a device substrate having a slope or a step on the surface, and a semiconductor device can be more appropriately manufactured.

As described above, according to the first embodiment, by correcting the drawing conditions of the pattern such that the pattern dimensional difference is reduced in boundary peripheral portion, the pattern can be formed with high dimensional accuracy on a substrate for which the height of the patterned surface changes. Further, according to the first embodiment, by correcting the dimension of the pattern drawn in the resist film 3 on the boundary peripheral portion, the pattern dimensional difference on the boundary peripheral portion can be reduced. Further, according to the first embodiment, by correcting (for example, reducing) the dimension of the pattern drawn on the resist film 3 on the boundary peripheral portion according to a previously measured or simulated pattern dimensional difference, the final product pattern dimensional difference on the boundary peripheral portion can be reduced.

### Second Embodiment

Next, a second embodiment in which the drawing condition is corrected by correcting an irradiation amount of the electron beam will be described. FIG. 11 is a flowchart showing an example of a drawing method according to a second embodiment.

As shown in FIG. 3, for the first embodiment, in order to reduce the pattern dimensional difference for the boundary peripheral portion, drawing data is corrected/adjusted by changing a dimension of the pattern drawn on the resist film 3.

In contrast to this, as shown in FIG. 11, in the second embodiment, the calculator 4 performs a correction by varying the irradiation amount of the electron beam EB as the correction of the drawing conditions for the pattern (step S41).

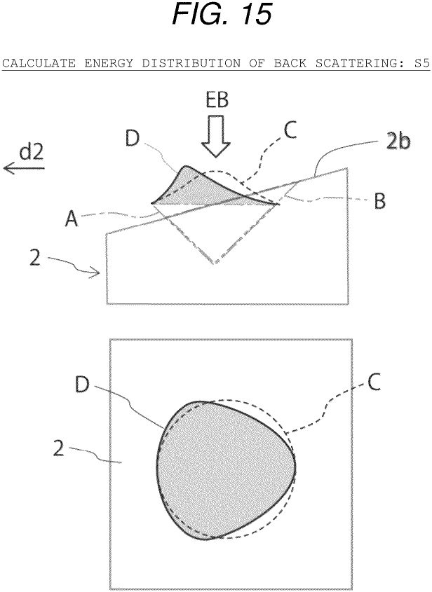

FIG. 12 is a view showing an example of a correction step of an irradiation amount shown in the flowchart of FIG. 11 in the drawing method according to the second embodiment. In the example shown in FIG. 12, the calculator 4 corrects a dose amount (that is, the irradiation amount) of the electron beam EB to which the resist film 3 on the slope boundary peripheral portion 2e is exposed.

On the other hand, in the example shown in FIG. 12, the calculator 4 maintains the dose amount (the design value) set in advance without correcting the dose amount of the electron beam EB with which the resist film 3 outside the slope boundary peripheral portion 2e is irradiated. More specifically, in this example, the adjustment of the dose amount of the electron beam EB is a reducing of the dose amount (relative to the normal dose amount) according to the pattern dimensional difference.

FIG. 13 is a descriptive view illustrating an example of a correction method of the irradiation amount in the drawing method according to the second embodiment. The dose amount after the correction can be determined, for example, by using the method shown in FIG. 13. In the example shown in FIG. 13, regarding the reference pattern P0 (for example, a line pattern) on the drawing data 11, the correction data, in which a plurality of dose amounts (DOSE-1, DOSE-2, DOSE-3, ...) and the formation result of the pattern P4 on the mask blank 2A corresponding to each dose amount are correlated to each other, is stored in advance in the calculator 4 or a storage device that can read the data from the calculator 4.

The calculator 4 extracts the pattern P4, which has the dimension that coincides with the dimension of the pattern P1 drawn on the resist film 3 on the slope boundary peripheral portion 2e, from the correction data (that is, the formation result of the plurality of patterns P4). The calculator 4 sets the dose amount, which corresponds to the extracted pattern P4, as the dose amount on the slope boundary peripheral portion 2e, that is, the dose amount after the correction. When the pattern P4, which has the dimension that coincides with the dimension of the pattern P1 drawn on the resist film 3 on the slope boundary peripheral portion 2e, is not present in the correction data, the calculator 4 may determine the dose amount to be used by using a calculation or estimation such as linear interpolation.

In FIGS. 12 and 13, an example of correcting the dose amount of the electron beam EB, with which the resist film 3 on the slope boundary peripheral portion 2e is irradiated, has been described, but the correction of the dose amount by using the same method can be applied to the electron beam EB with which the resist film 3 on the step boundary peripheral portion 2f is irradiated.

According to the second embodiment, by correcting the dose amount of the electron beam EB with which the resist film 3 on the boundary peripheral portion is irradiated, the pattern can be formed with high dimensional accuracy on the substrate in which the height of the surface changes, by using a simple method.

### Third Embodiment

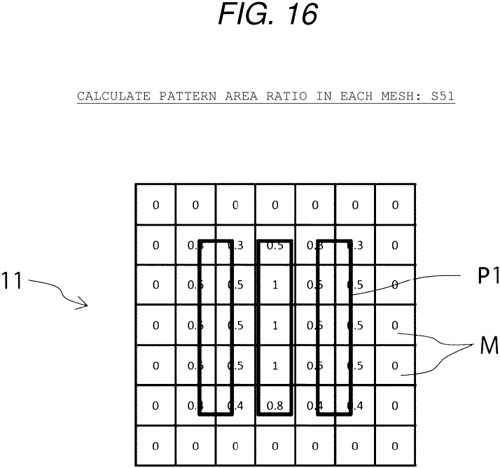

Next, a third embodiment of performing proximity effect correction will be described. FIG. 14 is a flowchart showing an example of a drawing method according to the third embodiment.

When the pattern is drawn on the substrate 2 for manufacturing the master plate (photomask, template), the resist film 3 is formed on the surface of the substrate 2. The pattern is drawn on the resist film 3 by irradiating the resist film 3 on the surface of the substrate 2 with the electron beam EB. The electron beam EB with which the substrate 2 is irradiated is back scattered by the substrate 2. The back scattering may additionally expose the resist film 3 on the surface of the substrate 2. A proximity effect in which the dimension of a pattern fluctuates from the design value as a result of back scattering is known. Specifically, in a place where the pattern density is high, since the back scattering from the surrounding pattern features becomes cumulatively larger, the dimension of the pattern in a high pattern density region becomes larger than the design value. On the other hand, in a place where the pattern density is low, since the cumulative back scattering amount is lower, the dimension of the pattern may be smaller than the design value. In order to ensure the dimensional accuracy of the pattern, it is generally desirable to correct for these proximity effects.

In the correction of a proximity effect, the irradiation amount of the electron beam EB is controlled based on an energy distribution of the anticipated back scattering. A Gaussian distribution is often used as the energy distribution of the back scattering. However, when the pattern is drawn on a substrate 2 having a step or a slope as in the substrates 2A to 2C, the energy distribution of the back scattering might not be uniform. That is, the energy distribution of the back scattering is different for the flat portions, the slope portions, and the step portions. In this case, when just a Gaussian distribution is always used as the energy distribution of the back scattering, the proximity effect cannot be properly corrected. However, the drawing apparatus 1 according to the third embodiment is configured to appropriately correct for proximity effects regardless of the surface shape of the substrate 2.

Specifically, the calculator 4 acquires the drawing data 11 and the height related data 12 from the outside and then calculates the energy distribution for the back scattering according to the change amount in the height of the surface of the substrate 2 based on the acquired height related data 12 (step S5). That is, the calculator 4 calculates different energy distributions for each of flat portion 2a, flat portion 2c, the slope portion 2b, and the step portion 2d.

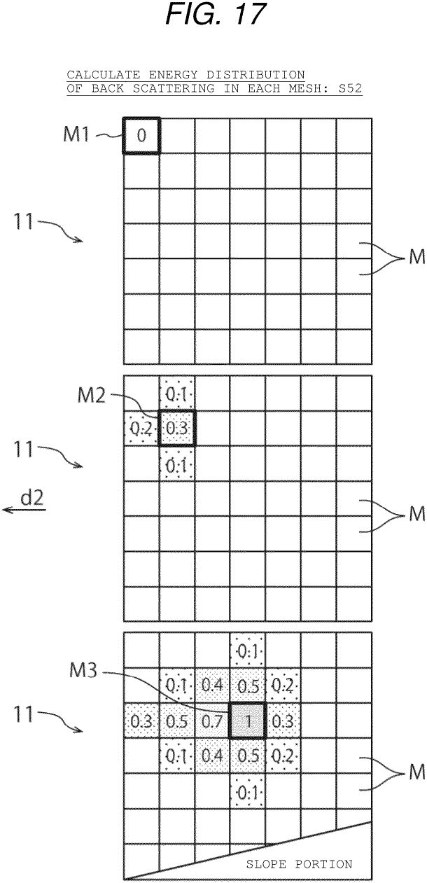

The calculation of the energy distribution of the back scattering for the slope portion 2b will be described with reference to a specific example. FIG. 15 is a descriptive view illustrating an example of a calculation step of an energy distribution of a back scattering in the drawing method according to the third embodiment. FIG. 15 shows, as a cross-sectional view and a plan view, a region B in which the one-shot electron beam EB, with which the slope portion 2b is irradiated, is back scattered in the substrate 2 and the energy distribution D of the back scattering. FIG. 15 also shows, as a comparison with the slope portion 2b, a region A in which the one-shot electron beam EB, with which the flat portion is irradiated, is back scattered in the substrate 2 and the energy distribution C generated by the back scattering.

In the example shown in FIG. 15, the energy distribution C of the back scattering for the flat portion is a Gaussian distribution. In contrast to this, as shown in FIG. 15, the energy distribution D of the back scattering in the slope portion 2b is calculated as a distribution different from the Gaussian distribution C. More specifically, in the example shown in FIG. 15, the energy distribution D for the slope portion 2b is calculated as a distribution in which a peak of the energy amount deviates from the Gaussian distribution C toward the tilt orientation d2 of the slope portion.

FIG. 16 is a descriptive view illustrating an example of the calculation step of the energy distribution of the back scattering in additional detail. In the example shown in FIG. 16, the drawing data 11 is data for the slope portion 2b. In a calculation step of the energy distribution (step S5), the calculator 4 first divides the drawing data 11 into a plurality of meshes M as shown in FIG. 16, and then calculates a pattern area ratio in each mesh M corresponding to the slope portion 2b (step S51). The pattern area ratio is a numerical value of 0 to 1, which indicates the ratio of an area of the pattern P1 with respect to an area of the mesh M for each mesh M. As shown in FIG. 16, the mesh M having a large region occupied by the pattern P1 has a large pattern area ratio.

FIG. 17 is a descriptive view illustrating an example of the calculation step of the energy distribution of the back scattering following FIG. 16. After calculating the pattern area ratio, the calculator 4 calculates the energy distribution of the back scattering in each mesh M corresponding in position to the slope portion 2b (step S52). In other words, the calculator 4 calculates the energy distribution of the back scattering generated when the region on the slope portion corresponding to each mesh M is irradiated with the electron beam EB corresponding to the portion of pattern P1 included in each mesh M. The calculation of the energy distribution of the back scattering in each mesh M follows, for example, a function, which is obtained based on a Monte Carlo simulation of the back scattering for the slope portion 2b, or a function that approximates (that is, simplifies) the function. The calculation of the energy distribution of the back scattering in each mesh M may be performed based on a table indicating the energy amount for each mesh M obtained based on the experimental results.

FIG. 17 shows the energy distribution of the back scattering generated by the electron beam EB with which a region on the slope portion 2b corresponding to each of the meshes M1 to M3 is irradiated according to the pattern P1 included in each of the meshes M1 to M3 of interest. The numerical values in each of the meshes M1 to M3 and M in FIG. 17 indicate the relative energy amount of the back scattering. More specifically, the energy amount described in each of the meshes M1 to M3 and M in FIG. 17 is a value obtained by setting the maximum value to 1. In FIG. 17, the energy amount of the meshes M1 to M3 of interest coincides with the pattern area ratio (see FIG. 16) corresponding to each of the meshes M1 to M3.

In FIG. 17, each of the meshes M1 to M3, M is filled with dots having a density corresponding to the magnitude of the energy amount of the back scattering. Further, in FIG. 17, the slope portion 2b is schematically shown in order to represent the height of the region on the slope portion 2b corresponding to each of the meshes M1 to M3 and M. As shown in FIG. 17, the energy amount becomes 0, in the mesh M1 in which the pattern P1 is not included, that is, the pattern area ratio is 0, and in the mesh M1 which is separated from the meshes M2 and M3 including the pattern P1. This is because the mesh M1 not only does not generate the back scattering by the electron beam EB with which the substrate is irradiated according to the any portion of pattern P1 inside mesh M1, but is also not affected by the back scattering by the electron beam EB used to form the pattern P1 in the other meshes.

On the other hand, in the mesh M2 having the pattern area ratio of 0.3, the energy distribution over the mesh M2 and the surrounding mesh M is calculated by using the back scattering generated by the electron beam EB with which the substrate is irradiated in writing the pattern P1 included in the mesh M2. This is because the back scattering of the electron beam EB according to the pattern P1 of the mesh M2 affects not only the mesh M2 but also the surrounding meshes M.

In the mesh M3 having the maximum pattern area ratio of 1, the energy distribution over a wider range of the meshes M3 and M is calculated by using the back scattering generated by the electron beam EB with which the substrate is irradiated according to the pattern P1 included in the mesh M3. As shown in FIG. 17, the energy distribution of the back scattering in the slope portion 2b is not an isotropic distribution centered on the meshes M2 and M3 of interest but is an anisotropic distribution that is unevenly distributed more on the tilt orientation d2 side of the slope portion.

Although a specific calculation method of the energy distribution of the back scattering according to the slope portion 2b has been described, the Gaussian distribution described above can be calculated as the energy distribution of the back scattering for the flat portions. By using the same method as the slope portion 2b, the energy distribution of the back scattering for the step portion 2d can be calculated, for example, according to a function, which is obtained based on Monte Carlo simulation of the energy distribution of the back scattering for the step portion 2d, or a function that approximates (that is, simplifies) the function.

After calculating the energy distribution of the back scattering, the calculator 4 calculates an integrated energy distribution as shown in FIG. 14 (step S6). The integrated energy distribution is a distribution obtained by integrating the calculated energy distribution for each mesh. FIG. 18 is a descriptive view illustrating an example of a calculation step of an integrated energy distribution shown in the flowchart of FIG. 14 in the drawing method according to the third embodiment. From the drawing data 11 shown in FIGS. 16 and 17, the integrated energy distribution shown in FIG. 18 is calculated. The integrated energy amount described in each mesh in FIG. 18 is a value converted with the maximum value as 1.

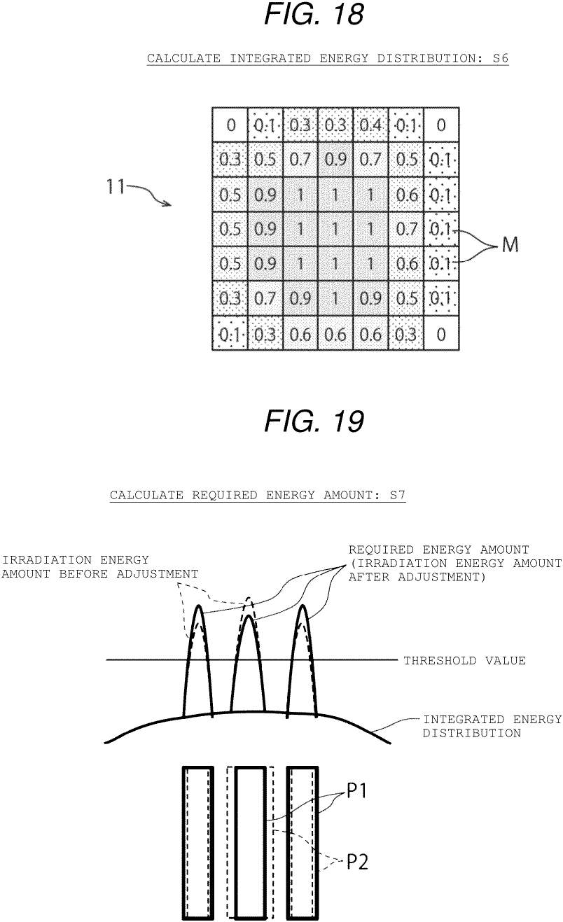

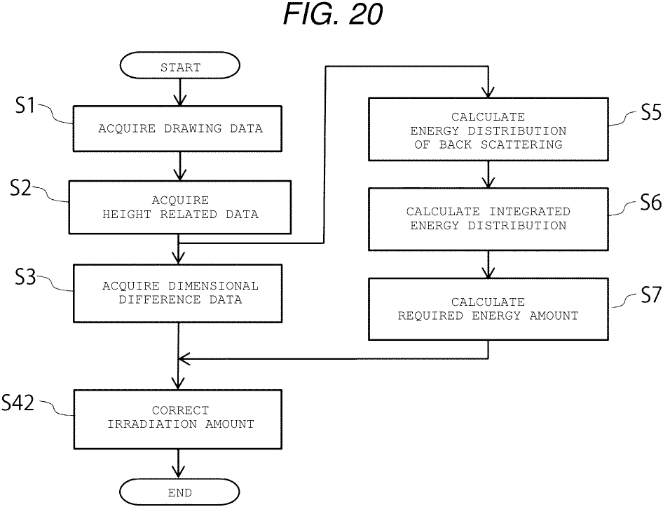

After calculating the integrated energy distribution, as shown in FIG. 14, the calculator 4 calculates the required energy amount based on the calculated integrated energy distribution (step S7). FIG. 19 is a descriptive view illustrating an example of a calculation step of the required energy amount shown in the flowchart of FIG. 14. In FIG. 19, the required energy amount (µC) in the slope portion 2b is calculated for each shot. FIG. 19 shows the pattern P1 corresponding to the required energy amount for each shot for convenience of explanation. The resist film 3 on the substrate 2 on which the pattern P1 is drawn is exposed not only by the electron beam EB but also by the back scattering. That is, not only an irradiation energy of the electron beam EB directly applied but also an energy from the back scattering is applied to the resist film 3. Therefore, the required energy amount (dose) must be calculated in consideration of the energy amount supplied by the back scattering. Therefore, as shown in FIG. 19, the calculator 4 first defines the irradiation energy amount of the electron beam EB for each shot to which the integrated energy amount according to the integrated energy distribution is added. The defined irradiation energy amount is the irradiation energy amount before the proximity effect correction.

Next, the calculator 4 sets the energy amount of a predetermined ratio (for example, 50%) with respect to the maximum value of the irradiation energy amount before the adjustment, as a threshold value. Thereafter, the calculator 4 adjusts the irradiation energy amount for each shot such that the distribution width (the horizontal width in FIG. 19) of the irradiation energy amount for each shot is the same at the threshold value. The irradiation energy amount after the adjustment is calculated as the required energy amount. The calculated required energy amount is used in the control device 5 for adjusting the irradiation amount supplied directly by the electron beam EB for writing the pattern. In this way, the proximity effect is corrected. When the proximity effect is not corrected, as shown in the pattern P2 indicated by the broken line in FIG. 19, a plurality of adjacent patterns P2 having the same width in the design data are in fact drawn as patterns having different widths. On the other hand, when correcting the proximity effect according to the third embodiment, as shown in the pattern P1 indicated by the solid line in FIG. 19, the plurality of adjacent patterns P1 having the same width in the design data can be appropriately drawn as the patterns P1 having the same width on the substrate 2.

According to the third embodiment, in addition to correcting the drawing data 11 such that the pattern dimensional difference is reduced in the pattern corresponding to the boundary peripheral portion, the proximity effect can be corrected more generally. As a result, a pattern can be formed on a substrate for which the height of the surface changes with higher dimensional accuracy.

### Fourth Embodiment

FIG. 20 is a flowchart showing an example of a drawing method according to a fourth embodiment. In the third embodiment, the proximity effect can be corrected by adjusting the pattern dimensions written.

In contrast to this, as shown in FIG. 20, the correction of the proximity effect may be performed by correcting/adjusting the irradiation amount rather than the pattern dimension written.

At least a part of the calculator 4 shown in FIGS. 1A and 1B may be configured with hardware or configured with software. In a case of being configured with the software, a program for implementing at least a part of the functions of the calculator 4 may be stored in a recording medium such as a flexible disk or a CD-ROM and may be read by a computer and executed. The recording medium is not limited to a removable medium such as a magnetic disk or an optical disk but may be a fixed recording medium such as a hard disk device or a memory. Further, a program that implements at least a part of the functions of the calculator 4 may be distributed via a communication line (including wireless communication) such as the Internet. Further, the program may be distributed via a wired line such as the Internet or a wireless line or stored in a recording medium in a state in which the program is encrypted, modulated, or compressed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern drawing method, comprising:
correcting a drawing parameter for a pattern drawn on a resist film on a surface of a substrate, the correction being based on drawing information, height information, and dimensional difference information, wherein
the drawing information is design data for drawing the pattern on the resist film by irradiating the resist film with an electron beam,
the height information indicates changes in surface height of the substrate,
the dimensional difference information includes differences between a dimension of a pattern as indicated in the design data and a dimension of a pattern formed on the substrate by processing the substrate using a resist film patterned according to the drawing information as a mask, and
the correction of the drawing parameter reduces a dimensional difference between design data and a pattern formed on a target portion on the surface of the substrate.

2. The pattern drawing method according to claim 1, wherein the correction of the drawing parameter includes adjusting a dimension of the pattern drawn on the resist film on the target portion.

3. The pattern drawing method according to claim 2, wherein the adjusting of the dimension of the pattern includes at least one of reducing the dimension of the pattern drawn on the resist film on the target portion or increasing the dimension of the pattern drawn on the resist film on the target portion.

4. The pattern drawing method according to claim 2, wherein the adjusting of the dimension of the pattern includes changing the drawing information indicating the pattern drawn to be on the resist film on the target portion.

5. The pattern drawing method according to claim 1, wherein the correction of the drawing parameter includes changing of an electron beam dose level with which the resist film on the target portion is irradiated.

6. The pattern drawing method according to claim 5, wherein the changing of the electron beam dose level includes at least one of reducing the electron beam dose level or increasing the electron beam dose level.

7. The pattern drawing method according to claim 1, wherein the target portion includes a boundary region between a first flat portion of the surface of the substrate at a first height and a second flat portion of the surface of the substrate at a second height different from the first height.

8. The pattern drawing method according to claim 7, wherein the boundary region is sloped surface.

9. The pattern drawing method according to claim 7, wherein the boundary region is substantially a step change from the first height to the second height.

10. The pattern drawing method according to claim 7, wherein the target portion further includes a flat portion of the surface of the substrate at the first or second height.

11. The pattern drawing method according to claim 1, wherein the target portion includes at least one of a first flat portion at a first height and connected to a lower end of a slope portion or a second flat portion at a second height connected to an upper end of the slope portion.

12. The pattern drawing method according to claim 1, wherein the substrate is an imprint template.

13. The pattern drawing method according to claim 1, wherein the substrate is a photomask.

14. A master plate manufacturing method, comprising:
correcting a drawing parameter for a pattern drawn on a resist film on a surface of a substrate, the correction being based on drawing information, height information, and dimensional difference information, wherein
the drawing information is design data for drawing the pattern on the resist film by irradiating the resist film with an electron beam,
the height information indicates changes in surface height of the substrate,
the dimensional difference information includes differences between a dimension of a pattern as indicated in the design data and a dimension of a pattern formed on the substrate by processing the substrate using a resist film patterned according to the drawing information as a mask, and
the correction of the drawing parameter reduces a dimensional difference between design data and a pattern formed on a target portion on the surface of the substrate;
drawing the pattern on the resist film on the surface of the substrate with the corrected drawing parameter using the electron beam;
developing the resist film on which the pattern has been drawn with the corrected drawing parameter; and
processing the substrate using the developed resist film as a mask.

15. The master plate manufacturing method according to claim 14, wherein the substrate is a photomask.

16. The master plate manufacturing method according to claim 14, wherein the substrate is a template for nanoimprint lithography.

17. The master plate manufacturing method according to claim 14, wherein the correction of the drawing parameter includes adjusting a dimension of the pattern drawn on the resist film on the target portion.

18. The master plate manufacturing method according to claim 14, wherein the correction of the drawing parameter includes changing of an electron beam dose level with which the resist film on the target portion is irradiated.

19. A pattern drawing apparatus, comprising:
a correction unit configured to correct a drawing parameter for a pattern drawn on a resist film on a surface of a substrate, the correction being based on drawing information, height information, and dimensional difference information, wherein:
the drawing information is design data for drawing the pattern on the resist film by irradiating the resist film with an electron beam,
the height information indicates changes in surface height of the substrate,
the dimensional difference information includes differences between a dimension of a pattern as indicated in the design data and a dimension of a pattern formed on the substrate by processing the substrate using a resist film patterned according to the drawing information as a mask, and
the correction of the drawing parameter reduces a dimensional difference between design data and a pattern formed on a target portion on the surface of the substrate; and
a drawing unit that draws the pattern on the resist film by irradiating the resist film with an electron beam according to the corrected drawing parameter.

20. The pattern drawing apparatus according to claim 19, wherein the correction of the drawing parameter includes adjusting a dimension of the pattern drawn on the resist film on the target portion.
